(19) United States
(12) Patent Application Publication
(10) Pub. No.: US 2026/0045769 A1
(43) Pub. Date: Feb. 12, 2026

(54) LIGHT EMITTING DEVICE

(71) Applicant: SEOUL VIOSYS CO., LTD., Ansan-si (KR)

(72) Inventors: Kyeongmo Yeo, Ansan-si (KR); Gonghee Choi, Ansan-si (KR)

(21) Appl. No.: 19/290,414

(22) Filed: Aug. 5, 2025

Related U.S. Application Data
(60) Provisional application No. 63/680,027, filed on Aug. 6, 2024.
(60) Provisional application No. 63/686,684, filed on Aug. 23, 2024.

(51) Int. Cl. H01S 5/183

(52) U.S. Cl. CPC H01S 5/18313; H01S 5/18361

(57) ABSTRACT

A light emitting device including a first mirror layer, a second mirror layer disposed on the first mirror layer, a cavity layer disposed between the first mirror layer and the second mirror layer and configured to generate light, and a mesa exposing side surfaces of the second mirror layer and the cavity layer, in which the second mirror layer includes at least one oxidized layer forming an aperture through which light generated in the cavity layer is configured to pass, and lengths of the oxidized layer from edges of the oxidized layer to the aperture are in the range of 0.95 to 1.05 times a diameter of the aperture.

### CROSS-REFERENCE TO RELATED APPLICATIONS

This application claims priority from and the benefit of U.S. Provisional Patent Application No. 63/680,027, filed Aug. 6, 2024, and U.S. Provisional Patent Application No. 63/686,684, filed Aug. 23, 2024, each of which is hereby incorporated by reference for all purposes as if fully set forth herein.

### BACKGROUND

### Field

Embodiments of the invention relate generally to a light emitting device, and more particularly, to a vertical cavity surface-emitting laser including an oxidized layer.

### Discussion of the Background

A vertical cavity surface-emitting laser (VCSEL) typically refers to a laser that emits a laser beam in a direction perpendicular to a substrate plane.

A typical VCSEL includes an N-DBR layer, a P-DBR layer, and an active layer disposed between the N-DBR layer and the P-DBR layer. Electrons and holes implanted through the N-DBR layer and the P-DBR layer generate light in the active layer, and light resonated in the N-DBR layer and the P-DBR layer can be amplified and emitted.

Electric current flowing perpendicular to the VCSEL needs to be confined to a small area, and etching and oxidation methods have been used to achieve this purpose. For example, the N-DBR/P-DBR layers and the active layer may be etched to form an isolated post by forming a ring-shaped trench, which can be used to focus the electric current into an aperture having a small area through formation of an oxidized layer.

The above information disclosed in this Background section is only for understanding of the background of the inventive concepts, and, therefore, it may contain information that does not constitute prior art.

### SUMMARY

Embodiments of the invention provide a light emitting device with low energy consumption, high reliability, and improved accuracy.

Embodiments of the invention also provide a light emitting device that can prevent deterioration in reliability due to cracks in a semiconductor layer.

Embodiments of the invention further provide a light emitting device capable of improving luminous efficacy by allowing electric current to intensively flow in a light emitting region.

Embodiments of the invention still provide a light emitting device that can prevent deterioration in performance and reliability due to foreign matter by increasing a penetration path of the foreign matter.

Embodiments of the invention also provide a light emitting device capable of improving straightness of light.

Additional features of the inventive concepts will be set forth in the description which follows, and in part will be apparent from the description, or may be learned by practice of the inventive concepts.

A light emitting device according to an embodiment includes a first mirror layer, a second mirror layer disposed on the first mirror layer, a cavity layer disposed between the first mirror layer and the second mirror layer and generating light, and a mesa exposing side surfaces of the second mirror layer and the cavity layer.

The second mirror layer may include at least one oxidized layer forming an aperture (AP) through which light generated in the cavity layer passes.

Lengths of the oxidized layer from edges of the oxidized layer to the aperture may be in the range of 0.95 to 1.05 times a diameter of the aperture.

The first mirror layer may include a plurality of first and second refractive index layers repeatedly stacked in sequence.

The cavity layer may include a first spacing layer on the first mirror layer, an active layer on the first spacing layer, and a second spacing layer on the active layer.

The second mirror layer may include a plurality of first and second refractive index layers repeatedly stacked in sequence on the oxidized layer.

The second mirror layer may further include a lower spacing layer disposed under the oxidized layer.

The lower spacing layer may be composed of a plurality of a plurality of lower spacing layers.

The oxidized layer may include a first oxidized layer and a second oxidized layer disposed on the first oxidized layer.

Lengths of the first oxidized layer may be longer than lengths of the second oxidized layer.

A thickness of the first oxidized layer may be different from a thickness of the second oxidized layer.

The second mirror layer may further include an upper spacing layer between the first oxidized layer and the second oxidized layer.

The second mirror layer may further include a plurality of sub-oxidized layers on an outer periphery of the second refractive index layer.

A length of each of the sub-oxidized layers from an edge of the sub-oxidized layer to a boundary of the sub-oxidized layer with the second refractive index layer may be shorter than the lengths of the oxidized layer.

A boundary surface connecting boundaries between the plurality of sub-oxidized layers and the second refractive index layers may form a curved surface.

The light emitting device may include a first pad region electrically connected to the first mirror layer and a second pad region at least partially disposed on the mesa and electrically connected to the second mirror layer.

The second mirror layer may include at least one oxidized layer forming an aperture through which light generated in the cavity layer passes.

The second pad region may include an open portion exposing an upper region of the mesa.

The open portion may overlap the aperture in plan view and may have a diameter greater than a diameter of the aperture.

The second pad region may include a contact region forming the open portion and a connecting region extending from the contact region.

The contact region may have a concave groove formed on an upper surface thereof.

The groove may be composed of a plurality of concave grooves arranged to be concentric with the open portion.

The light emitting device may further include a second electrode disposed on the mesa and electrically connected to the second mirror layer and an insulating layer disposed on the mesa and at least partially exposing the second electrode.

The insulating layer may include a plurality of sub-insulating layers.

A thickness of the oxidized layer may be thinner than a thickness of the first or second refractive index layer.

A thickness of the uppermost first refractive index layer of the second mirror layer may be greater than or equal to twice a thickness of other first refractive index layers thereof.

The thickness of the oxidized layer may be in the range of 0.3 to 0.4 times the thickness of the first or second refractive index layer.

A light emitting device according to another embodiment includes a semiconductor layer, an insulating layer, and a conductive layer. The semiconductor layer may include a first mirror layer, an active layer disposed on the first mirror layer, an oxidized layer disposed on the active layer, and a second mirror layer disposed on the oxidized layer. The insulating layer may cover the semiconductor layer and may include a first opening exposing the first mirror layer and a second opening exposing the second mirror layer. The conductive layer may be formed on the insulating layer and may include a first conductive layer electrically connected to the first mirror layer and a second conductive layer spaced apart from the first conductive layer and electrically connected to the second mirror layer. The semiconductor layer may include a multi-stepped groove formed by a first groove formed in the second mirror layer and a second groove formed inside the first groove. In addition, the second groove may penetrate the second mirror layer, the active layer, and the oxidized layer to expose the first mirror layer.

The first opening of the insulating layer may expose the first mirror layer in the second groove. The first conductive layer may be connected to the first mirror layer through the first opening of the insulating layer in the second groove.

The first conductive layer may include a first contact region, a first pad region, and a first connecting region. The first contact region may contact the first mirror layer and may have a ring shape with an open region. The first pad region may be disposed outside the first contact region and may be electrically connected to an external component. In addition, the first connecting region may be disposed outside the first contact region and may connect the first contact region to the first pad region.

The second conductive layer may include a second contact region, a second pad region, and a second connecting region. The second contact region may be disposed inside the first connecting region, may contact the second mirror layer, and may include a hole that exposes a light emitting surface through which light is emitted. The second pad region may be disposed outside the first contact region and may be electrically connected to the external component. In addition, the second connecting region may connect the first contact region to the second pad region through the open region of the first contact region.

The insulating layer may include a protective region disposed under the second contact region and formed with the second opening.

An inner surface of the protective region defining the second opening may be disposed between an inner wall and an outer wall of the second contact region of the second conductive layer.

The inner surface of the protective region defining the second opening may include a first inclined surface and a second inclined surface having different inclination angles, the second inclined surface being disposed under the first inclined surface.

The first inclined surface may have a greater inclination angle than the second inclined surface with respect to an upper surface of the second mirror layer.

A height of the second inclined surface may be less than or equal to 0.5 times a height of the first inclined surface.

The protective region may include a first region having a flat upper surface, a second region having the first inclined surface, and a third region having the second inclined surface. The first region, the second region, and the third region may be disposed one above another in sequence. In addition, the first region may have a greater width than the second region and the third region.

An inner surface of the second contact region defining the hole of the second contact region of the second conductive layer may have a multi-stepped structure.

The inner surface of the second contact region may include a first inner surface and a second inner surface disposed under the first inner surface. The first inner surface and the second inner surface may have different inclination angles with respect to the upper surface of the second mirror layer.

The first inner surface of the second contact region may have a greater inclination angle than the second inner surface.

An inner surface of the first contact region may include a first upper surface and a second upper surface disposed between the first inner surface and the second inner surface. The first upper surface may have a narrower width than the second upper surface.

The second contact region may have a ring shape with an open region.

The second contact region may have a circular shape with no open region.

The second connecting region may have a constant width from one end thereof connected to the second contact region to the other end thereof connected to the second pad region.

The second connecting region may have a gradually increasing width from one end thereof connected to the second contact region to the other end thereof connected to the second pad region.

The second connecting region may include a second-1 connecting region connected to the second contact region and a second-2 connecting region connected to the second pad region. The second-1 connecting region may have a constant width from one end thereof connected to the second contact region to the other end thereof connected to the second-2 connecting region. In addition, the second-2 connecting region may have a gradually increasing width from one end thereof connected to the second-1 connecting region to the other end thereof connected to the second pad region.

The second connecting region may include a second-1 connecting region connected to the second contact region and a second-2 connecting region connected to the second pad region. Here, the second-2 connecting region may have a predetermined angle with respect to the second-1 connecting region.

The first pad region may be disposed adjacent to one corner connected to one side surface of the semiconductor layer. In addition, the second pad region may be disposed adjacent to another corner connected to the one side surface of the semiconductor layer.

A separation distance between the first pad region and the second pad region may be less than a width of the first pad region and a width of the second pad region.

A length from one end of the second connecting region connected to the second contact region to the other end of the second connecting region connected to the second pad region may be less than a width of the second pad region.

Embodiments of the invention provide a light emitting device with low energy consumption, high reliability, and improved accuracy.

Embodiments of the invention provide a light emitting device that can prevent deterioration in reliability due to cracks in a semiconductor layer by covering a region between the semiconductor layer and a conductive layer with an insulating layer.

Embodiments of the invention provide a light emitting device capable of improving luminous efficacy by covering a region between a semiconductor layer and the conductive layer with an insulating layer such that electric current flows intensively in a light emitting region.

Embodiments of the invention provide a light emitting device that can prevent deterioration in performance and reliability due to foreign matter by covering a region between the semiconductor layer and the conductive layer with the insulating layer to increase a penetration path of the foreign matter.

Embodiments of the invention provide a light emitting device that can reflect light through an inclined surface of a conductive layer to improve straightness of light.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a top plan view of a light emitting device according to a first embodiment of the invention.

FIG. 2 is a cross-sectional view schematically showing layers forming the light emitting device according to the first embodiment.

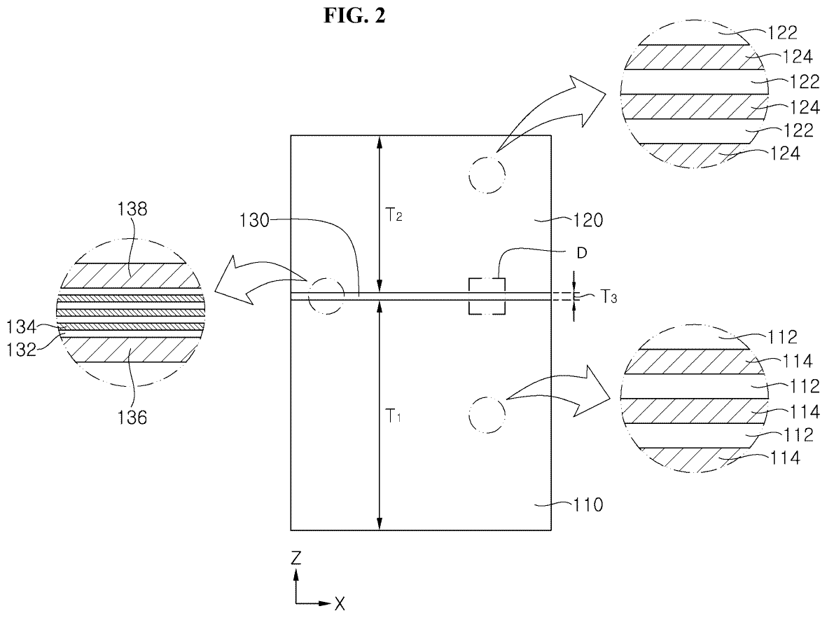

FIG. 3 is an enlarged view of Region D of FIG. 2.

FIG. 4 is a cross-sectional view taken along I-I′ of FIG. 1.

FIG. 5 is a partially enlarged view of FIG. 4.

FIG. 6 is a partially enlarged view of an upper surface of FIG. 4.

FIG. 7 is a cross-sectional view taken along II-II′ of FIG. 1.

FIG. 8 is a plan view of a light emitting device according to a second embodiment of the invention.

FIG. 9 is a cross-sectional view taken along A1-A2 of the light emitting device of FIG. 8.

FIG. 10 is another cross-sectional view taken along A3-A4 of the light emitting device according to the second embodiment.

FIG. 11 is an enlarged view of Region R shown in FIG. 10.

FIG. 12 is a plan view illustrating a conductive layer of a light emitting device according to a third embodiment.

FIG. 13 is a plan view illustrating a conductive layer structure of a light emitting device according to a fourth embodiment.

FIG. 14 is a plan view illustrating a conductive layer of a light emitting device according to a fifth embodiment.

FIG. 15 is a plan view illustrating a conductive layer structure of a light emitting device according to a sixth embodiment.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

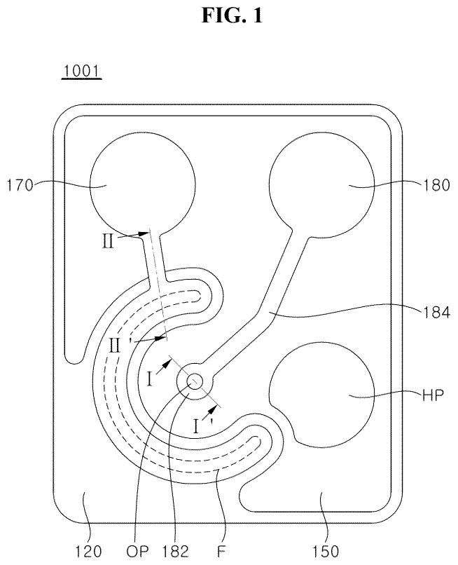

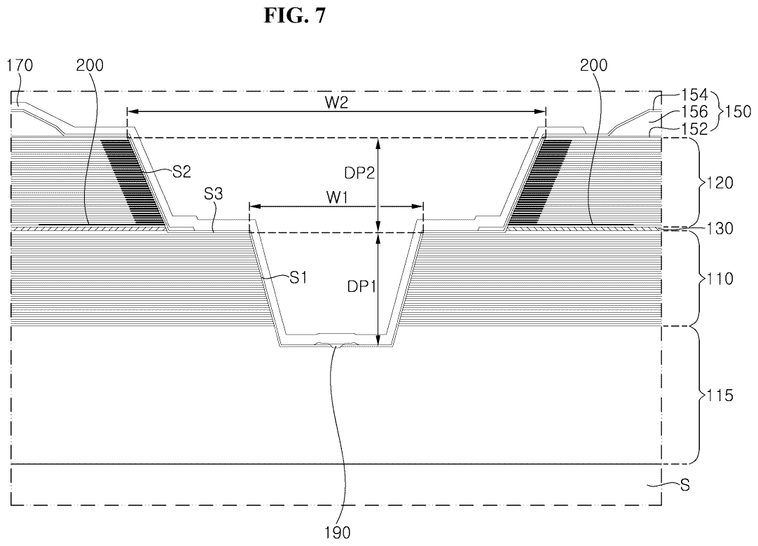

Referring to FIGS. 1 and 7, a light emitting device 1001 according to an embodiment includes a first mirror layer 110, a second mirror layer 120 disposed on the first mirror layer 110, a cavity layer 130 disposed between the first mirror layer 110 and the second mirror layer 120 and generating light, and a mesa M exposing side surfaces of the second mirror layer 120 and the cavity layer 130.

The light emitting device 1001 may be a vertical cavity surface-emitting laser (VCSEL), which may be a semiconductor laser diode. FIG. 1 is a top plan view of the light emitting device 1001 according to a first embodiment, in which light may be emitted through an open portion OP of an upper surface thereof. The light emitting device 1001 in FIG. 1 may be formed in various shapes, and the inventive concepts are not limited to a particular shape of the light emitting device.

The first mirror layer 110 may be a multilayer Distributed Bragg Reflector, in which reflective layers are stacked, such that light generated in the cavity layer 130 to be described below is repeatedly reflected from each layer to provide gain.

For example, the first mirror layer 110 may include a plurality of first and second refractive index layers 112, 114 repeatedly stacked in sequence.

The first refractive index layers 112 may have a first index of refraction and the second refractive index layers 114 may have a second index of refraction different from the first index of refraction. Due to the difference in index of refraction between the first refractive index layers 112 and the second refractive index layers 114, Fresnel reflection can occur at the interface therebetween. A first refractive index layer 112 and a second refractive index layer 114 sequentially stacked one above another may form a pair, and the first mirror layer 110 may include a plurality of pairs of first and second refractive index layers. For example, the first mirror layer 110 may include 39 pairs.

The first refractive index layers 112 and the second refractive index layers 114 may have various thicknesses, for example, in the range of 60 nm to 70 nm.

In one embodiment, the first refractive index layer 112 may be a GaAs layer having a higher index of refraction and the second refractive index layer 114 may be an AlGaAs layer having a lower index of refraction.

A thickness T1 of the first mirror layer 110 may have various values, for example, in the range of 4.5 μm to 5.5 μm.

The first mirror layer 110 may be doped with at least one n-type dopant, such as Si, C, Ge, Sn, Te, Pb, or the like. In particular, the first mirror layer 110 may be an n-type mirror layer.

The second mirror layer 120 may be a mirror layer disposed on the first mirror layer 110. The second mirror layer 120 may be a multilayer Distributed Bragg Reflector, in which reflective layers are stacked, such that light generated in a cavity layer 130 to be described below is repeatedly reflected from each layer to provide gain. The light generated in the cavity layer 130 may be emitted after being amplified through repeated reflection between the first mirror layer 110 and the second mirror layer 120.

For example, the second mirror layer 120 may include a plurality of first and second refractive index layers 122, 124 repeatedly stacked in sequence.

The first refractive index layers 122 may have a first index of refraction and the second refractive index layers 124 may have a second index of refraction different from the first index of refraction. Due to the difference in index of refraction between the first refractive index layers 122 and the second refractive index layers 124, Fresnel reflection can occur at the interface therebetween. A first refractive index layer 122 and a second refractive index layer 124 sequentially stacked one above another may form a pair and the second mirror layer 120 may include a plurality of pairs of first and second refractive index layers. For example, the second mirror layer 120 may include 24 pairs.

The first refractive index layers 122 and the second refractive index layers 124 may have various thicknesses T7, T8, for example, in the range of 60 nm to 70 nm.

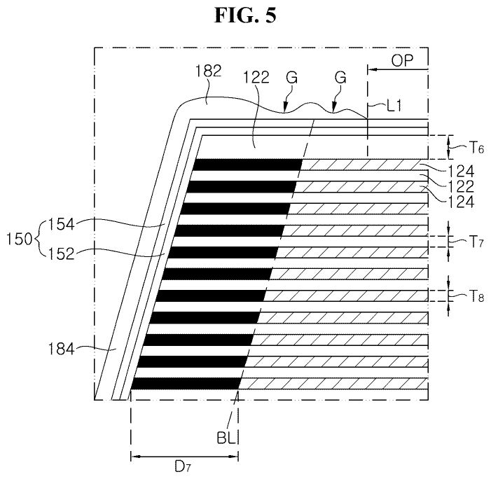

Referring to FIG. 5, a thickness T6 of the uppermost first refractive index layer 122 of the second mirror layer 120 may be greater than or equal to twice the thickness T7 of other first refractive index layers 122. For example, the thickness T6 of the uppermost first refractive index layer 122 may range from 170 nm to 180 nm.

In one embodiment, the first refractive index layer 122 may be a GaAs layer having a higher index of refraction and the second refractive index layer 124 may be an AlGaAs layer having a lower index of refraction.

A thickness T2 of the second mirror layer 120 may have various values, for example, in the range of 3 μm to 4 μm.

The second mirror layer 120 may be doped to have opposite conductivity to the first mirror layer 110. For example, the second mirror layer 120 may be doped with a p-type dopant, such as Mg. In particular, the second mirror layer 120 may be a p-type mirror layer.

The cavity layer 130 is disposed between the first mirror layer 110 and the second mirror layer 120, and may include an active layer 132, 134 that generates light.

The active layer 132, 134 is a light emitting layer formed on the first mirror layer 110 and may include a phosphide or nitride semiconductor, such as (Al, Ga, In) P or (Al, Ga, In) N. The active layer 132, 134 may be grown on the first mirror layer 110 by a technique well known in the art, such as MOCVD, MBE, or HVPE.

The active layer 132, 134 may also include a quantum-well structure (QW) including at least two barrier layers 132 and at least one well layer 134. Alternatively, the active layer 132, 134 may include a multi-quantum-well structure (MQW) including a plurality of barrier layers 132 and a plurality of well layers 134.

The wavelength of light emitted from the active layer 132, 134 may be adjusted by controlling the composition ratio of materials constituting the well layers 134. The well layers 134 may have the same element in common, for example, indium (In).

Each of the well layers 134 is interposed between the barrier layers 132 and has a narrower energy bandgap than the barrier layer 132.

The well layers 134 may include or be formed of a composition represented by InₓGa₍₁₋ₓ₎As (0<x<1), wherein the wavelength of the light emitted from the active layers may be controlled by the composition ratio (x) of In.

The barrier layers 132 may include or be formed of a composition represented by AlₓGa₍₁₋ₓ₎As (0<x<1).

The barrier layers 132 and the well layers 134 are alternately stacked one above another, preferably at least twice. A barrier layer 132 and a well layer 134 neighboring each other may form a pair. For example, the active layer 132, 134 may include three pairs.

The barrier layers 132 and the well layers 134 may have various thicknesses.

The first barrier layer 132 and the last barrier layer 132 of the active layer 132, 134 may have a greater thickness than other barrier layers 132 thereof. For example, the first barrier layer 132 may have a thickness of 5.5 nm to 6 nm, the last barrier layer 132 may have a thickness of 8.2 nm to 9 nm, and the other barrier layers 132 may be formed to a thinner thickness (for example, a thickness of 4 nm to 4.5 nm). The well layers 134 may be formed to a thickness that is thinner than the last barrier layer 132 and thicker than the other barrier layers 132, for example, a thickness of 7.8 nm to 8 nm.

In addition, the cavity layer 130 may further include a first spacing layer 136 and a second spacing layer 138. The first spacing layer 136 is a layer disposed on the first mirror layer 110 and may be interposed between the first mirror layer 110 and the active layer 132, 134. The second spacing layer 138 is a layer disposed on the active layer 132, 134 and may be interposed between the active layer 132, 134 and the second mirror layer 120.

A thickness of each of the first spacing layer 136 and the second spacing layer 138 may be in the range of 0.7 to 0.75 times the total thickness of the active layer 132, 134.

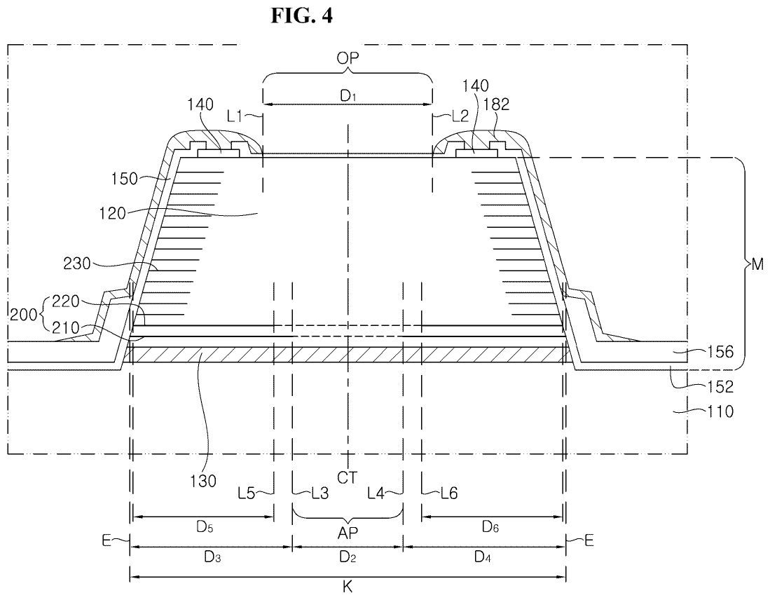

As shown in FIG. 4, the light emitting device 1001 may include a mesa M that exposes side surfaces of the second mirror layer 120 and the cavity layer 130. The mesa M may have a hill structure formed by etching the second mirror layer 120 and the cavity layer 130 to expose an upper surface of the first mirror layer 110. A side surface of the mesa M may form an inclined surface.

Since the second mirror layer 120 is exposed through the side surface of the mesa M, the second mirror layer 120 may further include an oxidized layer 200 formed through an oxidation process.

The oxidized layer 200 is formed by partial oxidation of the second mirror layer 120 and may have various configurations. The oxidized layer 200 may be formed through wet oxidation of the second mirror layer 120 and may be formed through partial oxidation of a region of the second mirror layer 120 having a high Al content. Accordingly, the oxidized layer 200 may be formed by gradually oxidizing the second mirror layer 120 from side surfaces of the mesa M towards the center of the mesa M.

Edge sides of the oxidized layer 200, which is formed within the mesa M, may be exposed through the side surfaces of the mesa M.

The oxidized layer 200 may form an aperture AP through which light generated in the cavity layer 130 passes.

Referring to FIG. 4, the aperture AP may be a circular opening having a diameter D2. The diameter D2 is a distance between opposite boundaries that meet a horizontal straight line passing through a center CT of the aperture AP and may be defined as a distance between vertical lines L3, L4 passing through the opposite boundaries of the aperture AP in FIG. 4. The diameter D2 may have various values.

Lengths D3, D4 of the oxidized layer 200 from the edges of the oxidized layer 200 to the aperture AP may be in the range of 0.95 to 1.05 times the diameter D2 of the aperture AP.

In FIG. 4, each of the length D3, D4 of the oxidized layer 200 from the edges of the oxidized layer 200 to the aperture AP may be defined as a length from a vertical line E passing through the edge of the oxidized layer 200 to a vertical line L3 or L4 passing through the boundary of the aperture AP. The length D3 from E to L3 may be the same as the length D4 from E to L4. For example, the ratio of D3, D2, and D4 (D3:D2:D4) may be 1:1:1.

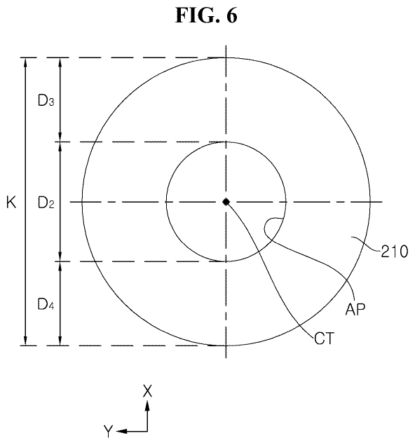

Referring to FIG. 4 and FIG. 6, a total sum K of D3, D2, and D4 may correspond to an overall diameter of the oxidized layer 200 and may be 18 μm. The diameter D2 of the aperture AP may range from 5.7 μm to 6.3 μm, more preferably 6 μm.

In plan view, the center of the oxidized layer 200 and the center of the aperture AP indicated by CT may coincide with each other.

The oxidized layer 200 may be formed to have various thicknesses T4. For example, the thickness T4 of the oxidized layer 200 may be thinner than the thicknesses T7, T8 of the first and second refractive index layers 122, 124 of the second mirror layer 120 described above. Specifically, the thickness T4 of the oxidized layer 200 may be in the range of 0.3 to 0.4 times the thickness T7 or T8 of the first or second refractive index layer 122 or 124.

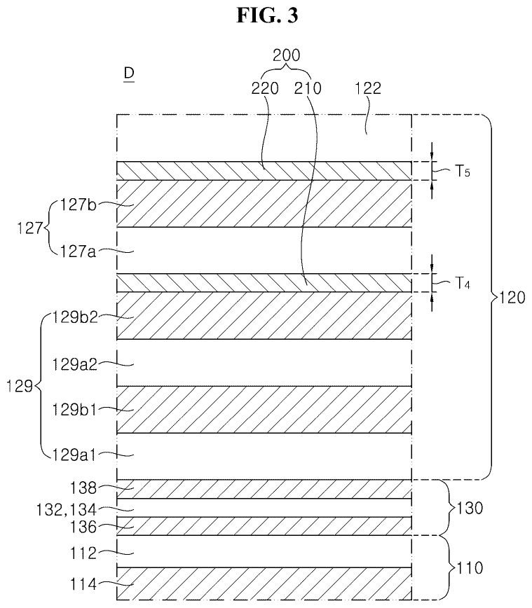

The oxidized layer 200 may be directly disposed on the cavity layer 130, without being limited thereto. In some embodiments, the second mirror layer 120 may further include a lower spacing layer 129 disposed under the oxidized layer 200, as shown in FIG. 3.

The lower spacing layer 129 is disposed between the oxidized layer 200 and the cavity layer 130 and may be formed in a bilayer structure, in which first and second spacers 129a, 129b having different compositions are sequentially stacked to form a pair.

The lower spacing layer 129 may be formed of a plurality of lower spacing layers. As shown in FIG. 3, the lower spacing layer 129 may include two pairs of first spacers 129a1, 129a2 and second spacers 129b1, 129b2 repeatedly stacked in sequence.

The oxidized layer 200 is not limited to a single layer structure, and may include a plurality of multilayer structures spaced in the vertical direction.

For example, the oxidized layer 200 may include a first oxidized layer 210 and a second oxidized layer 220 disposed above the first oxidized layer 210. Here, an opening formed in the lowermost oxidized layer, that is, in the first oxidized layer 210, is defined as the aperture AP.

Since the first oxidized layer 210 may have the same configuration or a similar configuration as the oxidized layer 200 described above, repeated descriptions of the same or similar configuration will be omitted.

The second oxidized layer 220 is an oxidized layer formed above the first oxidized layer 210 and may be formed through partial oxidation of a region of the second mirror layer 120 exposed through the side surface of the mesa M and having a high Al content.

The second oxidized layer 220 is formed within the mesa M, in which edge sides of the second oxidized layer 220 may be exposed through the side surfaces of the mesa M.

Referring to FIG. 4, the second oxidized layer 220 is also formed at a center thereof with an opening, which may be a circular opening concentric with the aperture AP of the first oxidized layer 210. The opening may have a larger diameter than the aperture AP.

Lengths D5, D6 of the second oxidized layer 220 from the edges of the second oxidized layer 220 to the opening may be different from the lengths D3, D4 of the first oxidized layer 210 from the edges of the first oxidized layer 210 to the aperture AP.

In FIG. 4, each of the lengths D5, D6 of the second oxidized layer 220 from the edges of the second oxidized layer 220 to the opening may be defined as a length from a vertical line passing through the edge of the second oxidized layer 220 to a vertical line L5 or L6 passing through the boundary of the opening. D5 may be the same as D6.

For example, the lengths D3, D4 of the first oxidized layer 210 may be longer than the lengths D5, D6 of the second oxidized layer 220.

The second oxidized layer 220 may be formed to have various thicknesses T5. For example, the thickness T4 of the first oxidized layer 210 may be different from the thickness T5 of the second oxidized layer 220. Specifically, the thickness T4 of the first oxidized layer 210 may be greater than the thickness T5 of the second oxidized layer 220.

The second mirror layer 120 may further include an upper spacing layer 127 between the first oxidized layer 210 and the second oxidized layer 220.

The upper spacing layer 127 is disposed between the first oxidized layer 210 and the second oxidized layer 220 and may be formed in a bilayer structure, in which first and second spacers 127a, 127b having different compositions are sequentially stacked to form a pair. The upper spacing layer 127 may be formed of a plurality of upper spacing layers.

The second mirror layer 120 may further include a plurality of sub-oxidized layers 230 each disposed on an outer periphery of the second refractive index layer 124.

The second refractive index layer 124 has a higher Al content than the first refractive index layer 122, and the sub-oxidized layers 230 may be formed by oxidation of an outer peripheral region of the second refractive index layer 124.

As the second refractive index layers 124 are provided in plural, the sub-oxidized layers 230 are also provided in plural.

Referring to FIG. 5, a length D7 of each of the sub-oxidized layers 230 from an edge of the sub-oxidized layer 230 to a boundary of the sub-oxidized layer 230 with the second refractive index layer 124 may be shorter than the lengths D3, D4 of the oxidized layers 200, 210.

In this embodiment, a boundary surface BL connecting the boundaries between the plurality of sub-oxidized layers 230 and the second refractive index layers 124 may be formed. The boundary surface BL may include a flat or curved surface (concave or convex). The boundary surface BL may also include a region in which the curvature thereof varies.

Referring to FIG. 1 and FIG. 4, the mesa M may include a first pad region 170 electrically connected to the first mirror layer 110, and a second pad region 180 at least partially disposed on the mesa M and electrically connected to the second mirror layer 120.

The first pad region 170 may be a pad region connected to a first electrode connected to the first mirror layer 110. The second pad region 180 may be a pad region connected to a second electrode 140 disposed on an upper surface of the second mirror layer 120. Here, the second electrode 140 is an electrode disposed on the mesa M and electrically connected to the second mirror layer 120, such that electric power can be applied through the first pad region 170 and the second pad region 180 to generate light in the active layer 132, 134.

The light emitting device 1001 may further include an insulating layer 150 disposed between the second pad region 180 and the mesa M. The insulating layer 150 may expose at least a region of the second pad region 180 and may be at least partially disposed on the mesa M.

The insulating layer 150 on the mesa M may be partially etched to expose the second electrode 140. The second pad region 180 may be connected to the second electrode 140 exposed by etching the insulating layer 150.

The insulating layer 150 may have a monolayer or multilayer structure. For example, the insulating layer 150 may include a plurality of sub-insulating layers 152, 154, 156. For example, the insulating layer 150 may include a first sub-insulating layer 152 and a second sub-insulating layer 154 on the first sub-insulating layer 152. In another example, the insulating layer 150 may further include a third sub-insulating layer 156 at least partially disposed between the first sub-insulating layer 152 and the second sub-insulating layer 154, as shown in FIG. 7. The first to third sub-insulating layers 152, 154, 156 may be formed of different materials and may have different thicknesses.

FIG. 4 illustrates an example wherein the insulating layer 150 includes the first and third sub-insulating layers 152, 156 and FIG. 5 illustrates an example wherein the insulating layer 150 includes the first and second sub-insulating layers 152, 154. However, the inventive concepts are not limited thereto, and the insulating layer 150 may include a greater number of sub-insulating layers in other embodiments.

The second pad region 180 is a finger-shaped pad region and may include a contact region 182 at least partially disposed on the mesa M and a connecting region 184 extending from the contact region 182.

In this embodiment, the second pad region 180 may include an open portion OP that exposes an upper region of the mesa. Light may be emitted through the open portion OP.

The open portion OP may be a circular opening, without being limited thereto. The open portion OP may be formed in the contact region 182. The contact region 182 may be formed in a variety of shapes, such as a ring shape as shown in FIG. 1, without being limited thereto.

As shown in FIG. 4, the open portion OP may overlap the aperture AP in plan view. A center of the open portion OP may coincide with a center CT of the aperture AP.

A diameter D1 of the open portion OP may be greater than the diameter D2 of the aperture AP. In particular, inner edge boundaries L1, L2 of the contact region 182 forming the open portion OP of the contact region 182 may be placed outside inner edge boundaries L3, L4 of the oxidized layer 200 forming the aperture AP.

In an embodiment, a concave groove G may be formed on an upper surface of the contact region 182. The groove G may be a concave groove concentric with the open portion OP. In addition, the groove G may be formed of a plurality of grooves, which may be arranged to be concentric with the open portion OP. Each of the grooves G may have a different depth, width, and curvature.

The light emitting device 1001 may further include a conductive semiconductor layer 115 formed under the first mirror layer 110 and doped to exhibit the same conductivity as the first mirror layer 110. In addition, the light emitting device 1001 may further include a growth substrate S, on which the conductive semiconductor layer 115 is grown, at the lowermost side of the light emitting device 1001.

The first pad region 170 is an electrode pad electrically connected to the conductive semiconductor layer 115 and may be formed in various forms. For example, the first pad region 170 may be formed to at least partially surround the contact region 182 of the second pad region 180.

For electrical connection between the first pad region 170 and the conductive semiconductor layer 115, an exposure groove F may be formed on an upper surface of the light emitting device 1001 to form an exposure region that exposes the conductive semiconductor layer 115. FIG. 7 is a cross-sectional view taken along II-II′ of FIG. 1, showing the exposure region in which the first mirror layer 110 is exposed through the exposure groove F. The exposure groove F may at least partially surround the contact region 182.

The exposure groove F may extend to a lower portion of the first mirror layer 110 to expose the conductive semiconductor layer 115. A portion of the exposure groove F may extend to an outer peripheral side of the light emitting device 1001.

Referring to FIG. 7, the exposure groove F may include a first slope S1 that starts from an upper surface of the exposed conductive semiconductor layer 115 and extends upwardly to form a sidewall of the first mirror layer 110, and a second slope S2 that forms a sidewall of the second mirror layer 120 and extends upwardly to an upper surface of the second mirror layer 120. A lower portion of the first slope S1 may include a side surface of the conductive semiconductor layer 115.

In the cross-sectional view of FIG. 7, a pair of first slopes S1 is formed on opposite sides with respect to the exposure groove F and a pair of second slopes S2 is formed on opposite sides with respect to the exposure groove F. A width between the pair of first slopes S1 may gradually narrow from top to bottom and a width between the pair of second slopes S2 may also gradually narrow from top to bottom.

The first slopes S1 may be connected to the second slopes S2. For example, the exposure groove may further include third slopes S3 each connecting the first slope S1 to the second slope S2.

A depth DP1 of the first slope S1 may be greater than a depth DP2 of the second slope S2. The uppermost width W1 between the first slopes S1 may be narrower than the uppermost width W2 between the second slopes S2. More particularly, the exposure groove F may be formed in a form that narrows from top to bottom.

In the cross-sectional view of FIG. 7, a space enclosed by the second slopes S2 may have a larger size than a space enclosed by the first slopes S1.

The first slopes S1 may have a greater inclination than the second slopes S2. In particular, the first slopes S1 may be steeper than the second slopes S2.

The third slope S3 is a sub-inclined plane connecting the first slope S1 and the second slope S2, and may be formed at a gentler inclination than the first slope S1 and the second slope S2 to allow the first pad region 170 to extend stably along the second slope S2 and the first slope S1.

The insulating layer 150 may cover the first slopes S1, the second slopes S2, and the third slopes S3, and may also cover an upper surface of the conductive semiconductor layer 115 exposed by the exposure groove F. Although FIG. 7 illustrates an example in which the insulating layer 150 includes first and second sub-insulating layers 152, 154, the inventive concepts are not limited thereto, and the insulating layer 150 may be formed in various shapes and may be provided in various numbers in other embodiments. For example, the insulating layer 150 may further include an additional sub-insulating layer 156 between the first and second sub-insulating layers 152, 154.

The upper surface of the conductive semiconductor layer 115 interposed between the pair of first slopes S1 may form a contact region electrically connected to the first pad region 170.

The sub-insulating layer 152 may cover a contact region and may be formed with an opening to partially expose the upper surface of the conductive semiconductor layer 115. An exposed region of the contact region exposed through the opening of the sub-insulating layer 152 may contact the first pad region 170, whereby the first pad region 170 can be electrically connected to the conductive semiconductor layer 115 through the contact region.

The light emitting device 1001 may further include an ohmic electrode 190 covering the contact region exposed by the sub-insulating layer 152. In particular, the ohmic electrode 190 may be disposed on the contact region between the pair of first slopes S1.

A downwardly depressed groove may be formed in the exposed region exposed by the sub-insulating layer 152 in the contact region. The groove is formed in the conductive semiconductor layer 115. Since an empty space formed by the groove is filled with the ohmic electrode 190, a contact surface area between the conductive semiconductor layer 115 and the ohmic electrode 190 contacting each other through the groove is increased, thereby increasing the contact area between the conductive semiconductor layer 115 and the ohmic electrode 190. In some embodiments, the ohmic electrode 190 may be omitted. In such case, the empty space formed by the groove may be filled with the first pad region 170.

The light emitting device 1001 may further include an additional pad region HP. Referring to FIG. 1, the additional pad region HP may have a different shape than the first pad region 170 and the second pad region 180 in top plan view. The additional pad region HP may be formed of the same material as the first pad region 170 or the second pad region 180. The additional pad region HP may be vertically spaced apart from the conductive semiconductor layer 115 and may be electrically isolated from the conductive semiconductor layer 115 or the second mirror layer 120. The additional pad region HP may include a thermally conductive material and may dissipate heat generated from the first mirror layer 110 and the second mirror layer 120, thereby preventing the DBR structure from being deformed due to heat. The additional pad region HP may be disposed in a light emission direction.

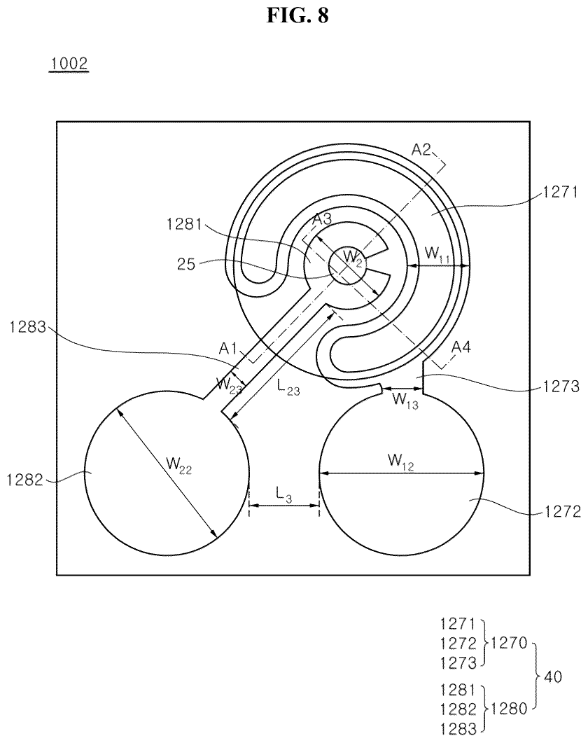

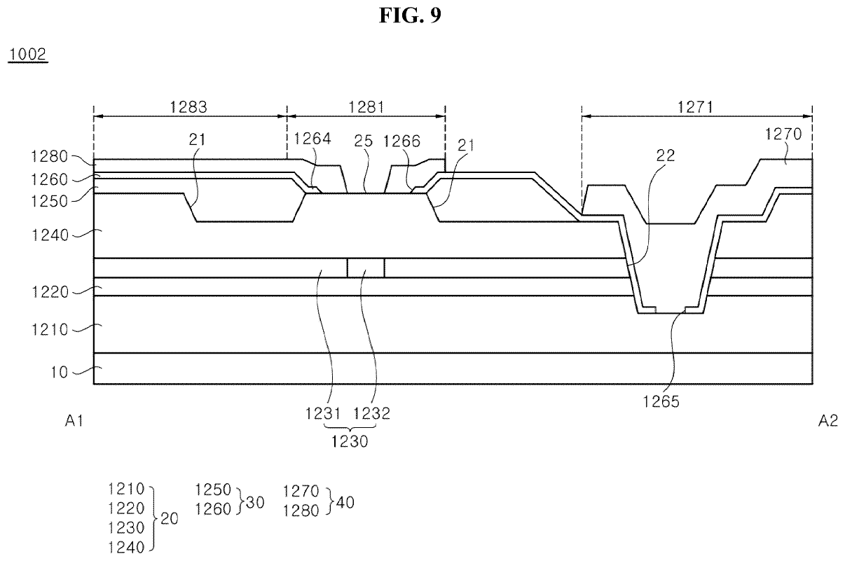

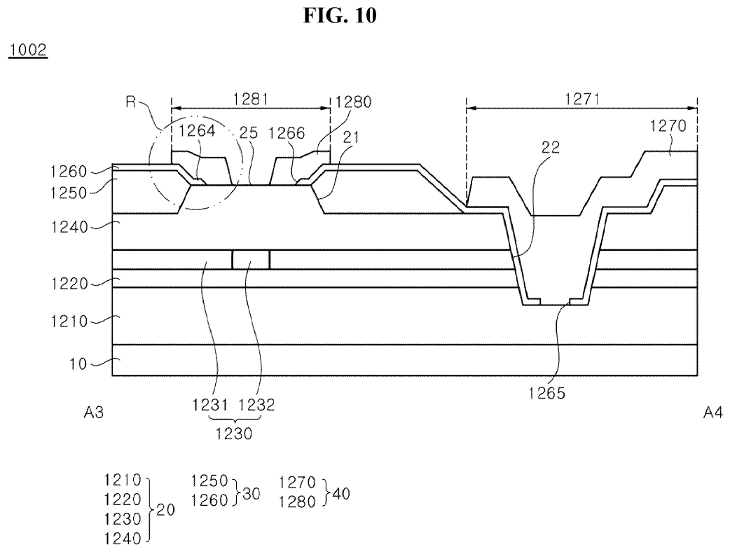

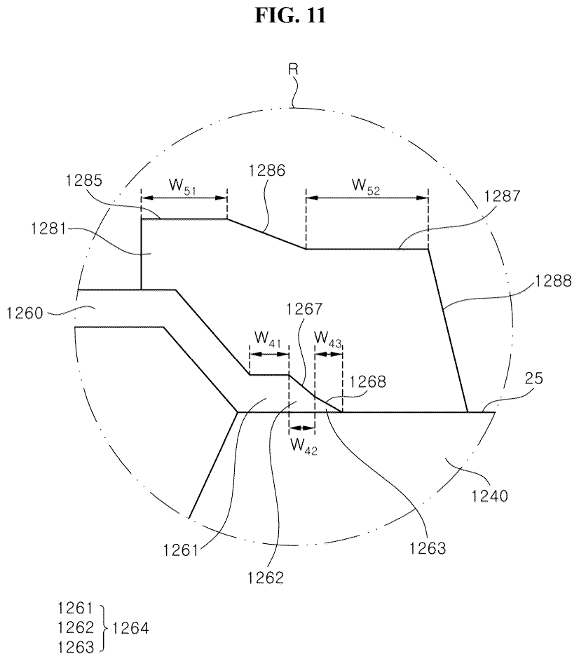

FIG. 8 to FIG. 11 are views of a light emitting device according to a second embodiment of the invention. FIG. 8 is a plan view of the light emitting device according to the second embodiment, FIG. 9 is a cross-sectional view taken along A1-A2 of the light emitting device of FIG. 8, FIG. 10 is another cross-sectional view taken along A3-A4 of the light emitting device according to the second embodiment, and FIG. 11 is an enlarged view of Region R shown in FIG. 10.

Referring to FIG. 8 to FIG. 10, the light emitting device 1002 according to this embodiment may include a substrate 10, a semiconductor structure 20, an insulating layer 30, and a conductive layer 40.

The substrate 10 may be a growth substrate for growth of the semiconductor structure 20 thereon. The type of the substrate 10 may vary depending on the type of the semiconductor structure 20 to be formed thereon. For example, the substrate 10 may be an n-type GaAs substrate.

The semiconductor structure 20 may be formed on the substrate 10. The semiconductor structure 20 may include a first mirror layer 1210, an active layer 1220, an oxidized layer 1230, and a second mirror layer 1240.

The first mirror layer 1210 may be formed on the substrate 10. According to this embodiment, the first mirror layer 1210 may include a plurality of n-type semiconductor layers. In addition, the first mirror layer 1210 may be formed by repeatedly stacking a plurality of semiconductor layers having different indices of refraction. For example, the first mirror layer 1210 may include a distributed Bragg reflector. For example, the first mirror layer 1210 may be formed by alternately stacking an AlGaAs layer having a lower Al content and an AlGaAs layer having a higher Al content.

The active layer 1220 may be formed on the first mirror layer 1210. The active layer 1220 may have a lower surface adjoining an upper surface of the first mirror layer 1210. The active layer 1220 can generate light through recombination of holes and electrons injected through the second mirror layer 1240 and the first mirror layer 1210. For example, the active layer 1220 may be formed in any one structure among a single well structure, a multi-well structure, a single quantum well structure, and a multi-quantum well (MQW) structure.

The oxidized layer 1230 may be formed between the active layer 1220 and the second mirror layer 1240. For example, the oxidized layer 1230 may be formed of an AlGaAs layer having a higher Al content than the second mirror layer 1240. The oxidized layer 1230 can limit a main region of the active layer 1220 that generates light.

Referring to FIG. 9, the oxidized layer 1230 may include an oxidized region 1231 and a window region 1232. The oxidized region 1231 may be formed to surround the window region 1232. The oxidized region 1231 may be formed by oxidizing a region of the oxidized layer 1230 other than the window region 1232. In addition, the window region 1232 may become a confined current flow path surrounded by the oxidized region 1231.

Since current flow is limited in the oxidized region 1231, electric current traveling from the second mirror layer 1240 to the first mirror layer 1210 can intensively flow through the window region 1232. The electric current can be injected to a region of the active layer 1220 disposed under the window region 1232 through a narrow region of the window region 1232. Accordingly, the active layer 1220 can intensively focus light in a narrow region disposed under the window region 1232. As such, the oxidized layer 1230 can limit the region of the active layer 1220, which generates and emits light, by restricting a current flow path to the window region 1232.

The second mirror layer 1240 may be formed on the oxidized layer 1230. According to this embodiment, the second mirror layer 1240 may include a plurality of p-type semiconductor layers. In addition, the second mirror layer 1240 may be formed by repeatedly stacking a plurality of semiconductor layers having different indices of refraction. For example, the second mirror layer 1240 may include a distributed Bragg reflector. For example, the second mirror layer 1240 may be formed by alternately stacking an AlGaAs layer having a lower Al content and an AlGaAs layer having a higher Al content.

In this embodiment, each of the first mirror layer 1210 and the second mirror layer 1240 may include a plurality of semiconductor layer pairs in which a plurality of semiconductor layers is stacked one above another. The first mirror layer 1210 and the second mirror layer 1240 may be formed by stacking a plurality of semiconductor layer pairs. For example, the number of semiconductor layer pairs in the second mirror layer 1240 may be less than the number of semiconductor layer pairs in the first mirror layer 1210. The number of semiconductor layer pairs of the second mirror layer 1240 may be 20 or more, and the number of semiconductor layer pairs of the first mirror layer 1210 may be 30 or more.

Referring to FIG. 9 and FIG. 10, the semiconductor structure 20 may include a plurality of grooves. The grooves formed in the semiconductor structure 20 may include a first groove 21 and a second groove 22 formed inside the first groove 21.

The first groove 21 may be formed such that a bottom surface of the first groove 21 includes the second mirror layer 1240, and the second groove 22 may be formed such that a bottom surface of the second groove 22 includes the first mirror layer 1210. The first groove 21 is formed inside the second mirror layer 1240 and may be concave in a downward direction from an upper surface of the second mirror layer 1240. Accordingly, the bottom surface of the first groove 21 may include the second mirror layer 1240. Due to the first groove 21 formed in the second mirror layer 1240, the upper surface of the semiconductor structure 20 corresponding to the upper surface of the second mirror layer 1240 may include a concave region and a convex region. More particularly, the second mirror layer 1240 may include a relatively thick region and a relatively thin region. According to this embodiment, the first groove 21 may be formed to at least partially surround a light emitting region from which the light emitting device 1002 emits light.

Further, the second groove 22 may be formed inside a predetermined first groove 21 among the plurality of first grooves 21. Here, the second groove 22 may be formed to penetrate the second mirror layer 1240, the oxidized layer 1230, and the active layer 1220, such that the first mirror layer 1210 is exposed therethrough. Thus, the bottom surface of the second groove 22 may include the first mirror layer 1210.

According to this embodiment, since the second groove 22 is formed inside the first groove 21, the first groove 21 and the second groove 22 are connected to each other. In addition, the first groove 21 has a greater diameter than the second groove 22. As such, with the first groove 21 and the second groove 22 connected to each other, the semiconductor structure 20 may include a groove having a multi-stepped inner wall. More particularly, the multi-stepped groove formed in the semiconductor structure 20 may be formed by performing an etching process twice.

Next, the processes of manufacturing the light emitting device 1002 according to this embodiment will be briefly described. First, the semiconductor structure 20 may be formed on the substrate 10 and the first groove 21 may be formed on a second mirror layer 1240. After the first groove 21 is formed, the oxidized region 1231 may be formed to surround the window region 1232 through partial oxidation of an oxidized layer 1230. After the oxidized region 1231 is formed, the second groove 22 may be formed to expose the first mirror layer 1210 by etching an inner region of the first groove 21. Through the two etching processes, a groove having a multi-stepped inner wall and exposing the first mirror layer 1210 may be formed on the semiconductor structure 20.

Generally, in order to form a groove for electrical connection between the first mirror layer 1210 and the conductive layer 40, the semiconductor structure 20 is etched deeply from the second mirror layer 1240 to the first mirror layer 1210 in a single etching process. Since the etching process is performed once, the inner wall of the groove formed in the semiconductor structure 20 becomes a planar surface, such as a vertical surface or an inclined surface, rather than a surface with a multi-stepped structure.

However, since the light emitting device 1002 according to this embodiment includes the second groove 22 having a smaller diameter than the first groove 21 on the inner surface of the first groove 21, the inner wall of the groove exposing the first mirror layer 1210 formed on the semiconductor structure 20 has a multi-stepped structure. Thus, in this embodiment, the inner wall of the groove having the multi-stepped structure and formed in the semiconductor structure 20 has an increased length and area than an inner wall of a groove having a planar structure. Accordingly, in this embodiment, a penetration path of foreign matter, such as moisture and dust, from the outside to the first mirror layer 1210 along the groove formed in the semiconductor structure 20 is increased, as compared with the groove having the inner wall of the planar structure. Therefore, the light emitting device 1002 according to this embodiment can prevent deterioration in performance and reliability due to moisture and dust by increasing the penetration path of foreign matter through the multi-stepped groove.

Furthermore, in the light emitting device 1002 according to this embodiment, the second groove 22 is formed in a region of the semiconductor structure 20, the thickness of which is reduced by the formation of the first groove 21. Accordingly, an etching depth for exposing the first mirror layer 1210 is reduced, as compared with when the first groove 21 is not formed. Therefore, the light emitting device 1002 according to this embodiment allows reduction in etching thickness of the semiconductor structure 20 to expose the first mirror layer 1210, thereby reducing the time and costs for the etching process.

The insulating layer 30 and the conductive layer 40 may be formed on the semiconductor structure 20. The insulating layer 30 may include a first insulating layer 1250 and a second insulating layer 1260. In addition, the conductive layer 40 may include a first conductive layer 1270 and a second conductive layer 1280. The insulating layer 30 may be formed to insulate the first conductive layer 1270 and the second conductive layer 1280 formed on the second mirror layer 1240.

According to this embodiment, the first insulating layer 1250 and the second insulating layer 1260 may be formed of an insulating material. In addition, the first insulating layer 1250 and the second insulating layer 1260 may be formed of the same insulating material or may include different insulating materials. For example, the first insulating layer 1250 and the second insulating layer 1260 may be formed of any one of silicon oxide (SiO₂), silicon nitride (SiN_{X}), polyimide, or benzocyclobutene (BCB). In addition, the first insulating layer 1250 may be formed of at least one of polyimide or BCB. Here, even when formed to have a thin thickness, the first insulating layer 1250 formed of a material having a low dielectric constant, such as BCB, can reduce parasitic capacity to prevent deterioration in performance of the light emitting device. In addition, the second insulating layer 1260 may be formed of at least one of silicon oxide or silicon nitride.

The first insulating layer 1250 may be formed to at least partially cover the upper surface of the second mirror layer 1240. The first insulating layer 1250 may be formed in a region in which the first conductive layer 1270 is formed. In particular, the first insulating layer 1250 may be formed under the first conductive layer 1270. In addition, the first insulating layer 1250 may fill the first groove 21 of the semiconductor structure 20. Referring to FIG. 9 and FIG. 10, an upper surface of the first insulating layer 1250 may be positioned higher than the convex region of the second mirror layer 1240.

The second insulating layer 1260 may be formed on the first insulating layer 1250 to cover the first insulating layer 1250. In addition, the second insulating layer 1260 may be formed to cover a region of the semiconductor structure 20. Here, the second insulating layer 1260 may cover a region of the second mirror layer 1240 disposed under a second contact region 1281 of the second conductive layer 1280.

In addition, the second insulating layer 1260 may be formed to cover not only the upper surface of the first insulating layer 1250 but also a region of the first groove 21 exposed through the first insulating layer 1250 and the second groove 22. More specifically, the second insulating layer 1260 may be formed to cover the oxidized layer 1230, the active layer 1220, and the first mirror layer 1210, which are exposed through the second groove 22.

Referring to FIG. 9 and FIG. 10, the second insulating layer 1260 may include a plurality of openings formed to penetrate from an upper surface of the second insulating layer 1260 to a lower surface of the second insulating layer 1260. The openings formed in the second insulating layer 1260 may include a first opening 1265 formed between a first contact region 1271 of the first conductive layer 1270 and the first mirror layer 1210 to expose the first mirror layer 1210. In addition, the openings of the second insulating layer 1260 may include a second opening 1266 formed between the second contact region 1281 of the second conductive layer 1280 and the second mirror layer 1240 to expose the second mirror layer 1240. According to this embodiment, the first opening 1265 of the second insulating layer 1260 is disposed inside the second groove 22 and the light emitting region of the light emitting device 1002 may be disposed inside the second opening 1266.

The first conductive layer 1270 and the second conductive layer 1280 may be formed on the insulating layer 30. The first conductive layer 1270 may be electrically connected to the first mirror layer 1210 and the second conductive layer 1280 may be electrically connected to the second mirror layer 1240. The first conductive layer 1270 and the second conductive layer 1280 may be formed of a conductive material. In addition, the first conductive layer 1270 and the second conductive layer 1280 may have at least one conductive material in common or may include different conductive materials. In addition, the first conductive layer 1270 and the second conductive layer 1280 may be formed as a single layer or multiple layers. The first conductive layer 1270 and the second conductive layer 1280 may have the same layer configuration or different layer configurations.

The first conductive layer 1270 and the second conductive layer 1280 may be spaced apart from each other. Here, the first conductive layer 1270 may be formed to partially surround the second conductive layer 1280.

Referring to FIG. 9, the second conductive layer 1280 may be formed on the first insulating layer 1250 and the second insulating layer 1260.

Referring to FIG. 8, the second conductive layer 1280 may include the second contact region 1281, a second pad region 1282, and a second connecting region 1283. The second pad region 1282 may be electrically connected to an external component, such as a circuit board. The second contact region 1281 may be electrically connected to the second mirror layer 1240. In addition, the second connecting region 1283 may be formed between the second contact region 1281 and the second pad region 1282, such that at one end thereof is connected to the second contact region 1281 and the other end thereof is connected to the second pad region 1282. Thus, the second conductive layer 1280 can apply a voltage to the second mirror layer 1240 after receiving the voltage from the external component.

A portion of the second connecting region 1283 and the second pad region 1282 may be disposed outside the first conductive layer 1270. Here, the outer side of the first conductive layer 1270 may include not only an outer region of the first conductive layer 1270, but also an upper region and a lower region thereof. Furthermore, another portion of the second connecting region 1283 and the second contact region 1281 may be disposed inside the first conductive layer 1270.

The second contact region 1281 may have a ring shape with an open region. In addition, the second connecting region 1283 may have an elongated shape to connect the second contact region 1281 and the second pad region 1282. In plan view of FIG. 8, both side surfaces of the second connecting region 1283 connecting the second contact region 1281 and the second pad region 1282 may have a straight shape. According to this embodiment, the second connecting region 1283 may have a constant width W23 from one end thereof connected to the second contact region 1281 to the other end connected to the second pad region 1282.

A width W22 of the second pad region 1282 may be greater than an outer width W21 of the second contact region 1281 and the width W23 of the second connecting region 1283 in parallel lines. In addition, the second pad region 1282 may have a larger area than the second contact region 1281.

In addition, the width W22 of the second pad region 1282 may be greater than a length L23 of the second connecting region 1283. The length L23 of the second connecting region 1283 may be greater than the width W21 of the second contact region 1281. Here, the length L23 of the second connecting region 1283 refers to a length from one end thereof connected to the second contact region 1281 to the other end thereof connected to the second pad region 1282.

Thus, the second pad region 1282 has a larger area than the second connecting region 1283 and the second contact region 1281. In this manner, the light emitting device 1002 can achieve improvement in heat dissipation performance through the second pad region 1282 having a large area. In addition, the light emitting device 1002 can facilitate electrical connection to an external configuration through the second pad region 1282 having a large area.

Referring to FIG. 9, the second contact region 1281 may contact the second mirror layer 1240 by covering a region of the second mirror layer 1240 exposed through the second opening 1266 of the second insulating layer 1260. Here, the second contact region 1281 may be formed between an inner wall of the second opening 1266 and the light emitting region of the light emitting device 1002. In particular, the second contact region 1281 may be formed to contact the second mirror layer 1240 outside the light emitting region. As such, the second conductive layer 1280 may be electrically connected to the second mirror layer 1240 through the second contact region 1281. Although not shown in this embodiment, an ohmic layer may be further formed between the second contact region 1281 and the second mirror layer 1240 to reduce contact resistance of the second conductive layer 1280 and the second mirror layer 1240.

Referring to FIG. 9, the first conductive layer 1270 may be formed on the second insulating layer 1260 covering the semiconductor structure 20. In addition, the first conductive layer 1270 may be formed such that the first groove 21 and the second groove 22 are at least partially filled with the first conductive layer 1270. Here, the first conductive layer 1270 may contact the first mirror layer 1210 exposed through the first opening 1265 of the second insulating layer 1260 inside the second groove 22. Accordingly, the first conductive layer 1270 may be electrically connected to the first mirror layer 1210 inside the second groove 22. Although not shown in this embodiment, an ohmic layer may be further formed between the first contact region 1271 and the first mirror layer 1210 to reduce contact resistance of the first conductive layer 1270 and the first mirror layer 1210.

Referring to FIG. 8, the first conductive layer 1270 may include a first contact region 1271, a first pad region 1272, and a first connecting region 1273. The first pad region 1272 may be electrically connected to an external component, such as a circuit board. The first contact region 1271 may be electrically connected to the first mirror layer 1210 in the second groove 22. The first connecting region 1273 is formed between the first contact region 1271 and the first pad region 1272, such that at one end thereof is connected to the first contact region 1271 and the other end thereof is connected to the first pad region 1272. Thus, the first conductive layer 1270 can apply a voltage received from the external component to the first mirror layer 1210.

The first contact region 1271 of the first conductive layer 1270 may be formed to surround the second contact region 1281 of the second conductive layer 1280 outside the second contact region 1281. In addition, the first connecting region 1273 and the first pad region 1272 may also be disposed outside the first contact region 1271.

The first contact region 1271 may have a ring shape with an open region. Here, the second connecting region 1283 of the second conductive layer 1280 may pass through an open region between opposite ends of the first contact region 1271 to connect the second contact region 1281 to the second pad region 1282. Referring to FIG. 8, the first connecting region 1273 has a gradually decreasing width W13 from one end thereof connected to the first contact region 1271 to the other end thereof connected to the first pad region 1272. However, the structure of the first connecting region 1273 is not limited thereto. For example, in some embodiments, the first connecting region 1273 may have a gradually increasing width from one end thereof to the other thereof or may have a constant width from one end to the other end thereof.

In addition, a width W12 of the first pad region 1272 may be greater than a width W11 of the first contact region 1271 and the width W13 of the first connecting region 1273 in parallel lines. Here, the width W11 of the first contact region 1271 refers to a length from an inner side thereof to an outer side thereof. In addition, the first pad region 1272 may have a larger area than the first contact region 1271. The light emitting device 1002 can achieve improvement in heat dissipation performance through the first pad region 1272 having a large area. In addition, the light emitting device 1002 can facilitate electrical connection to an external configuration through the first pad region 1272 having a large area.

The first pad region 1272 of the first conductive layer 1270 and the second pad region 1282 of the second conductive layer 1280 are regions electrically connected to an external configuration. Accordingly, the first pad region 1272 and the second pad region 1282 may be formed to have a larger area than other regions of the first conductive layer 1270 and the second conductive layer 1280.

Referring to FIG. 8, in this embodiment, the first pad region 1272 of the first conductive layer 1270 and the second pad region 1282 of the second conductive layer 1280 may be disposed adjacent to one side surface of the light emitting device 1002. Here, the second pad region 1282 may be disposed adjacent to one corner connected to the one side surface of the light emitting device 1002. In addition, the first pad region 1272 may be disposed adjacent to another corner connected to the one side surface of the light emitting device 1002. Here, a separation distance L3 between the first pad region 1272 and the second pad region 1282 may be less than the width W12 of the first pad region 1272 and the width W22 of the second pad region 1282.

Referring to FIG. 9 and FIG. 10, the second insulating layer 1260 may be disposed in a region between the conductive layer 40 and the semiconductor structure 20. A region of the second insulating layer 1260 may be formed to cover a region of the upper surface of the semiconductor structure 20 under the second contact region 1281 of the second conductive layer 1280. The region of the second insulating layer 1260 may be a protective region 1264.

When a conductive layer is formed on the semiconductor layer, cracks can occur in the semiconductor layer due to various stresses, such as excessive force applied to the semiconductor layer or a difference in coefficient of thermal expansion between the semiconductor layer and the conductive layer. For example, cracks can be generated in a region where a lower corner of the conductive layer of the semiconductor layer is positioned. Here, when overcurrent or overvoltage, such as a surge, is applied to the cracks through the conductive layer, the cracks can grow larger, thereby destroying the semiconductor layer and thus causing the light emitting device to fail.

To prevent this problem, the light emitting device according to this embodiment may have a protective region 1264 of the second insulating layer 1260 disposed between the corner of the second contact region 1281 of the second conductive layer 1280 and the semiconductor structure 20.

Thus, in the light emitting device 1002 according to this embodiment, the protective region 1264 of the second insulating layer 1260 is disposed between the lower corner of the second conductive layer 1280 and the semiconductor structure 20 to prevent cracking of the semiconductor structure 20 due to the second conductive layer 1280, thereby improving reliability.

Furthermore, when the semiconductor layer adjoins the conductive layer 40, electric current applied to the conductive layer 40 can be focused on the lower corner of the conductive layer 40 to flow into the semiconductor layer.

However, according to this embodiment, the protective region 1264 of the second insulating layer 1260 prevents the current from being applied to the semiconductor structure 20 through the corner of the second conductive layer 1280. Furthermore, the current can flow through the second conductive layer 1280 to be applied to the semiconductor structure 20 in a contact region between the second conductive layer 1280 and the semiconductor structure 20. Here, the contact region is disposed inside the opening of the second insulating layer 1260.

Accordingly, the protective region 1264 of the second insulating layer 1260 between the second conductive layer 1280 and the semiconductor structure 20 allows the electric current to intensively flow through the second contact region 1281. In particular, the light emitting device 1002 according to an embodiment may allow the electric current to intensively flow through the contact region adjacent to the light emitting region, thereby allowing more intensive generation and emission of light within the light emitting region. In this case, the amount of light generated in a region other than the light emitting region can be reduced due to the reduced amount of current therein. Thus, the light emitting device 1002 according to the embodiment can reduce the amount of light generated in the region other than the light emitting region to reduce light loss, thereby improving luminous efficacy.

According to this embodiment, an inner surface of the second insulating layer 1260 defining the opening disposed in the first contact region 1271 and the second contact region 1281 may include an inclined surface. Furthermore, the inner surface of the second insulating layer 1260 defining the opening may include a plurality of inclined surfaces. Referring to FIG. 11, the inner surface of the second insulating layer 1260 defining the opening may include a first inclined surface 1267 and a second inclined surface 1268 disposed under the first inclined surface 1267.

The first inclined surface 1267 and the second inclined surface 1268 of the second insulating layer 1260 may have different inclinations with respect to the second mirror layer 1240. For example, the first inclined surface 1267 may have a greater inclination angle than the second inclined surface 1268. Here, the inclination angle may refer to an angle formed between the upper surface of the first mirror layer 1210 or the second mirror layer 1240 and the inclined surface of the second insulating layer 1260. Alternatively, the inclination angle may refer to an angle formed between an extension of the upper surface of the first mirror layer 1210 or the second mirror layer 1240 and an extension of the inclined surface of the second insulating layer 1260.

According to this embodiment, when the first inclined surface 1267 and the second inclined surface 1268 have different inclination angles, the inner surface of the second insulating layer 1260 may have a greater length than when the first inclined surface 1267 and the second inclined surface 1268 have the same inclination angle. More particularly, when the second insulating layer 1260 has a curved structure, the inner surface of the second insulating layer 1260 has a greater length than when the second insulating layer 1260 includes a single inclined surface. Therefore, in the light emitting device 1002 according to this embodiment, a contact area between the second insulating layer 1260 and the conductive layer 40 can be increased through the increase in length of the inner surface of the second insulating layer 1260, thereby improving adhesion between the second insulating layer 1260 and the conductive layer 40.

Furthermore, a height of a lower end of the first inclined surface 1267 may be less than or equal to 0.5 times a height of an upper end of the first inclined surface 1267. More particularly, a height from the upper surface of the second mirror layer 1240 to a point where the first inclined surface 1267 meets the second inclined surface 1268 may be less than or equal to 0.5 times a height from the upper surface of the second mirror layer 1240 to the upper end of the first inclined surface 1267. Here, the height of the upper end of the first inclined surface 1267 is a height of the second opening 1266.

According to this embodiment, the protective region 1264 of the second insulating layer 1260 may include a first region 1261, a second region 1262, and a third region 1263. The first region 1261 is a region of the protective region 1264 that has a flat upper surface of the second insulating layer 1260. The second region 1262 is a region having the first inclined surface 1267 of the second insulating layer 1260. In addition, the third region 1263 is a region having the second inclined surface 1268 of the second insulating layer 1260.

According to this embodiment, a width W41 of the first region 1261 of the protective region 1264 may be greater than a width W42 of the second region 1262 and a width W43 of the third region 1263. In addition, the second region 1262 and the third region 1263 of the protective region 1264 may have the same width or different widths.

In deposition of the conductive layer 40 on the insulating layer 30, a greater inclination angle of the insulating layer 30 makes it more difficult to deposit the conductive layer 40 thereon. Accordingly, in the light emitting device 1002 according to this embodiment, the width W42 of the second region 1262 may be greater than the width W43 of the third region 1263, thereby making it easier to form the conductive layer 40.

More particularly, in the light emitting device 1002 according to this embodiment, the area of a region adjoining the conductive layer 40 is increased by increasing the width of a region where deposition of the conductive layer 40 is relatively difficult, and the inclination angle is decreased, thereby making it easier to form the conductive layer 40.

According to this embodiment, the second conductive layer 1280 may include a hole that opens the light emitting region. An inner wall defining the hole of the second conductive layer 1280 is an inner surface of the second conductive layer 1280 formed along the periphery of the light emitting region. Thus, the hole of the second conductive layer 1280 may function as a path that guides light emitted from the second mirror layer 1240 to travel.

In addition, the second conductive layer 1280 may reflect light. Accordingly, the inner surface of the second conductive layer 1280 may reflect light traveling toward the inner surface such that the light is directed toward the top of the light emitting region.

In this embodiment, the light emitting device 1002 may be formed such that the inner surface of the second conductive layer 1280 surrounding the hole of the second conductive layer 1280 has a multi-stepped structure. Thus, the second conductive layer 1280 may include a first upper surface 1285, a second upper surface 1287 disposed below the first upper surface 1285, a first inner surface 1286, and a second inner surface 1288 disposed below the first inner surface 1286.

The first upper surface 1285 of the second conductive layer 1280 may be disposed between an outer surface of the second conductive layer 1280 and the first inner surface 1286, and the second upper surface 1287 may be disposed between the first inner surface 1286 and the second inner surface 1288. More specifically, in the second conductive layer 1280, one end of the first upper surface 1285 adjoins an upper end of the outer surface and the other end of the first upper surface 1285 adjoins an upper end of the first inner surface 1286. Further, in the second conductive layer 1280, one end of the second upper surface 1287 adjoins a lower end of the first inner surface 1286 and the other end thereof adjoins an upper end of the second inner surface 1288. Here, the inner surface of the second conductive layer 1280 defining the hole of the second conductive layer 1280 may include the first inner surface 1286, the second inner surface 1288, and the second upper surface 1287 disposed therebetween. In addition, a width W52 of the second upper surface 1287 may be greater than a width W51 of the first upper surface 1285.

According to this embodiment, light emitted from the light emitting surface 25 and not traveling toward the top of the light emitting region may be reflected by the second inner surface 1288 to be directed to the top of the light emitting region. In addition, light directed from the top of the second inner surface 1288 in a direction other than the top of the light emitting region may be reflected by the first inner surface 1286. The light reflected by the first inner surface 1286 may be directed toward the top of the light emitting region. As such, the light emitting device 1002 allows light to be focused into a certain region by the first inner surface 1286 and the second inner surface 1288 of the second conductive layer 1280, thereby improving straightness of light emitted to the outside.

The first inner surface 1286 and the second inner surface 1288 of the second conductive layer 1280 may be inclined surfaces each having an inclination with respect to the second mirror layer 1240. For example, each of the first inner surface 1286 and the second inner surface 1288 of the second conductive layer 1280 may have an inclination angle of about 60 degrees to about 90 degrees.

Further, the first inner surface 1286 and the second inner surface 1288 of the second conductive layer 1280 may have different inclinations with respect to the upper surface of the second mirror layer 1240. For example, the first inner surface 1286 of the second conductive layer 1280 may have a greater inclination than the second inner surface 1288. The first inner surface 1286 having a greater inclination can focus light into a smaller region. Thus, the second conductive layer 1280 including the first inner surface 1286 having a greater inclination than the second inner surface 1288 can further improve straightness of light emitted from the light emitting device 1002.

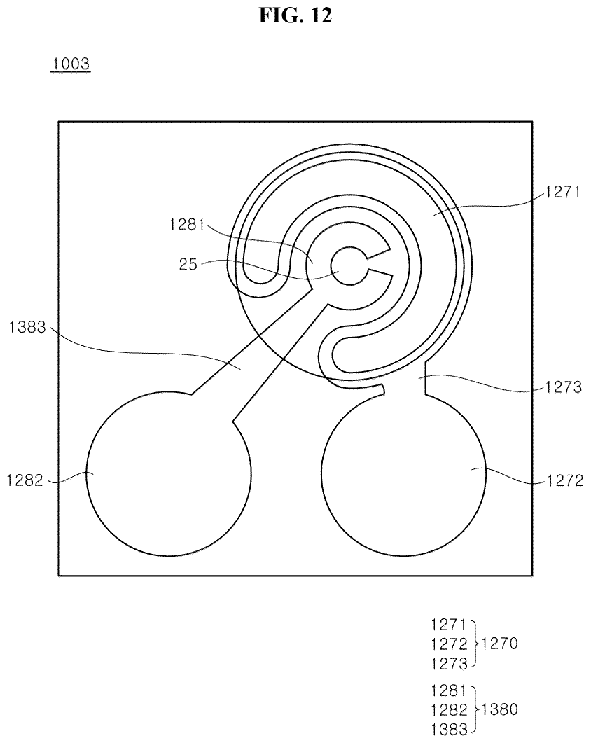

FIG. 12 to FIG. 15 are exemplary views of light emitting devices according to third to sixth embodiments. Specifically, FIG. 12 to FIG. 15 are plan views illustrating conductive layers of the light emitting devices according to the third to sixth embodiments.

Referring to FIG. 12 to FIG. 15, each of the light emitting devices 1003, 1004, 1005, 1006 according to the third to sixth embodiments may include a first conductive layer 1270 and a second conductive layer 1380; 1480; 1580; 1680.

Here, the first conductive layers 1270 of the light emitting devices 1003, 1004, 1005, 1006 according to the third through sixth embodiments have substantially the same structure as the first conductive layer 1270 of the light emitting device 1002 according to the second embodiment (FIG. 8). Since the configuration of the first conductive layer 1270 of the light emitting device 1002 has been described above with reference to FIG. 8, repeated descriptions with regards to the first conductive layers 1270 of the light emitting devices 1003, 1004, 1005, 1006 according to the third to sixth embodiments will be omitted.

The second conductive layers 1380, 1480, 1580, 1680 of the light emitting devices 1003, 1004, 1005, 1006 according to the third to sixth embodiments have different structures than the second conductive layer 1280 of the light emitting device 1002 according to the second embodiment exemplarily illustrated in FIG. 8.

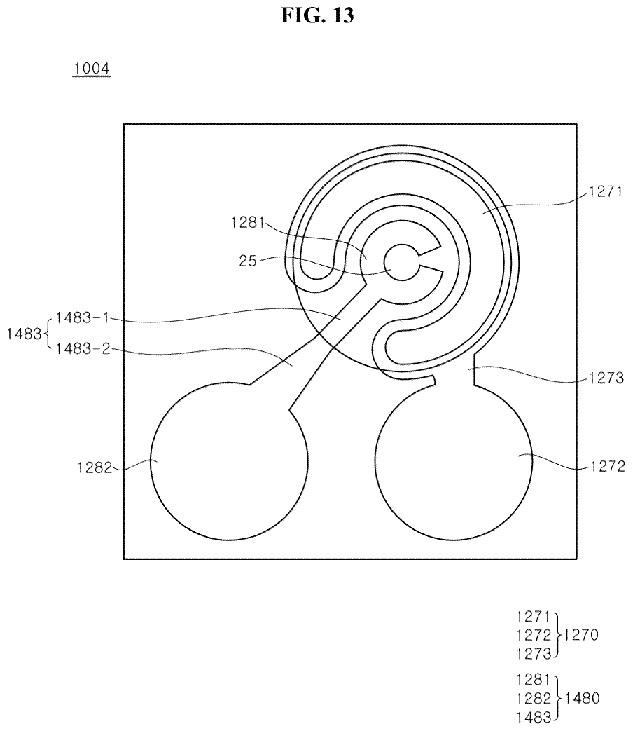

Referring to FIG. 12 and FIG. 13, each of the second conductive layers 1380, 1480 of the light emitting devices 1003, 1004 according to the third and fourth embodiments may include a second contact region 1281, a second connecting region 1383; 1483, and a second pad region 1282. Here, the second connecting regions 1383; 1483 and the second pad regions 1282 are substantially the same as the second connecting region 1281 and the second pad region 1282 of the light emitting device 1002 according to the second embodiment shown in FIG. 8.

Referring to FIG. 12 and FIG. 13, one end of each of the second connecting regions 1383, 1483 of the light emitting devices 1003, 1004 according to the third and fourth embodiments may be connected to the second contact region 1281 and the other end thereof may be connected to the second pad region 1282. Here, the opposite ends of the second connecting regions 1383, 1483 have different widths. For example, one end of the second connecting regions 1383, 1483 may have a narrower width than the other end of the second connecting regions 1383, 1483.

In plan view of FIG. 12, both sides of the second connecting region 1383 of the light emitting device 1003 according to the third embodiment may have a straight shape. In this embodiment, the second connecting region 1383 of the light emitting device 1003 according to the third embodiment may have a gradually increasing width from one end to the other end thereof.

In plan view of FIG. 13, the second connecting region 1483 of the light emitting device 1004 according to the fourth embodiment may include a second-1 connecting region 1483-1 and a second-2 connecting region 1483-2 connected to each other. One end of the second-1 connecting region 1483-1 may be connected to the second contact region 1281 and the other end thereof may be connected to one end of the second-2 connecting region 1483-2. In addition, the second-2 connecting region 1483-2 may be connected at one end thereof to the other end of the second-1 connecting region 1483-1 and connected at the other end thereof to the second pad region 1282. Here, the second-1 connecting region 1483-1 of the light emitting device 1004 according to the fourth embodiment may have a constant width from one end to the other end thereof, and the second-2 connecting region 1483-2 may have a gradually increasing width from one end to the other end thereof.

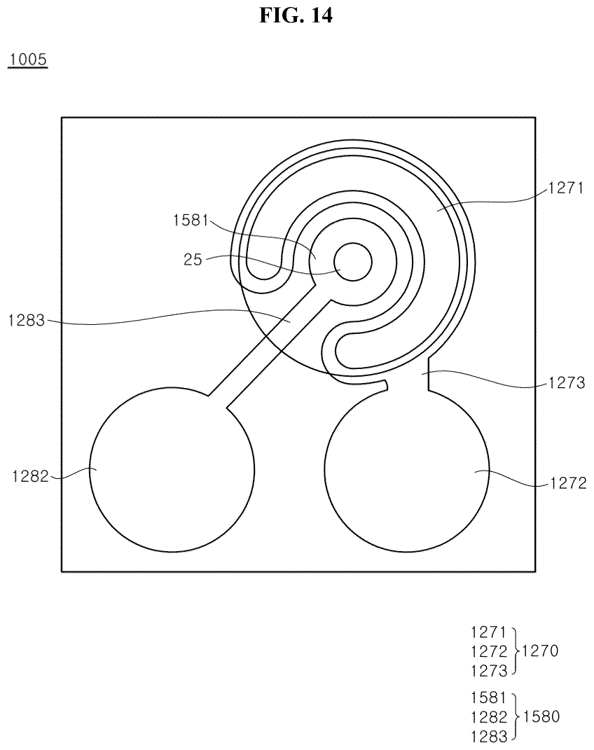

Referring to FIG. 14, the second conductive layer 1580 of the light emitting device 1005 according to the fifth embodiment may include a second contact region 1581, a second connecting region 1283, and a second pad region 1282. The second conductive layer 1580 of the light emitting device 1005 according to the fifth embodiment has substantially the same structure as the second conductive layer 1280 of the light emitting device 1002 according to the second embodiment shown in FIG. 8 except for the second contact region 1581 thereof.

According to the fifth embodiment, the second contact region 1581 may have a circular shape with no open regions. Furthermore, an inner surface of the second contact region 1581 is formed with a hole that exposes the light emitting surface 25 corresponding to the light emitting region. More particularly, the second contact region 1581 may have a ring shape exposing the light emitting surface 25 of the light emitting device 1005 from the inner surface thereof.

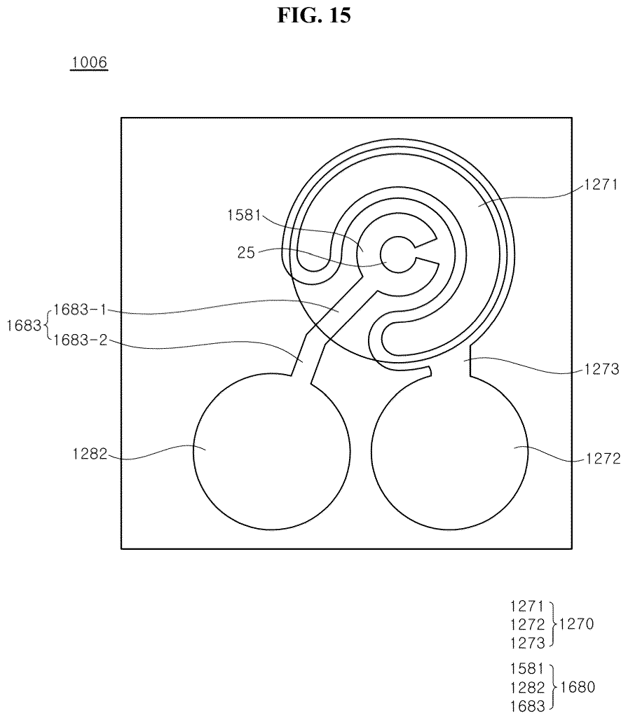

Referring to FIG. 15, the second conductive layer 1680 of the light emitting device 1006 according to the sixth embodiment may include a second contact region 1581, a second connecting region 1683, and a second pad region 1282. The second conductive layer 1680 of the light emitting device 1006 according to the sixth embodiment has substantially the same structure as the second conductive layer 1680 of the light emitting device according to the fifth embodiment shown in FIG. 14 except for the second connecting region 1683 thereof.

The second connecting region 1683 of the light emitting device 1006 according to the sixth embodiment may include a second-1 connecting region 1683-1 and a second-2 connecting region 1683-2 connected to each other. The second-1 connecting region 1683-1 may be connected at one end thereof to the second contact region 1581 and connected at the other end thereof to one end of the second-2 connecting region 1683-2. In addition, the second-2 connecting region 1683-2 may be connected at one end thereof to the other end of the second-1 connecting region 1683-1 and connected at the other end thereof to the second pad region 1282. Here, the second-2 connecting region 1683-2 may be formed to have a predetermined angle with respect to the second-1 connecting region 1683-1. Thus, the second connecting region 1683 of the light emitting device 1006 according to the sixth embodiment may have a bent shape.

The structure of the conductive layer of the light emitting device according to the embodiments of the invention is not limited to the structures according to the first to sixth embodiments. The conductive layer may have various structures through combination of the shapes of the connecting regions, the connecting regions, and the pad regions disclosed in the first to sixth embodiments.

Although certain embodiments and implementations have been described herein, other embodiments and modifications will be apparent from this description. Accordingly, the inventive concepts are not limited to such embodiments, but rather to the broader scope of the 5 appended claims and various obvious modifications and equivalent arrangements as would be apparent to a person of ordinary skill in the art.

What is claimed is:

1. A light emitting device comprising:
a first mirror layer;
a second mirror layer disposed on the first mirror layer;
a cavity layer disposed between the first mirror layer and the second mirror layer and configured to generate light; and
a mesa exposing side surfaces of the second mirror layer and the cavity layer,
wherein the second mirror layer comprises at least one oxidized layer forming an aperture through which light generated in the cavity layer is configured to pass, and
wherein lengths of the oxidized layer from edges of the oxidized layer to the aperture are in the range of 0.95 to 1.05 times a diameter of the aperture.

2. The light emitting device according to claim 1, wherein the first mirror layer comprises a plurality of first and second refractive index layers repeatedly stacked in sequence.

3. The light emitting device according to claim 1, wherein the cavity layer comprises a first spacing layer on the first mirror layer, an active layer on the first spacing layer, and a second spacing layer on the active layer.

4. The light emitting device according to claim 1, wherein the second mirror layer comprises a plurality of first and second refractive index layers repeatedly stacked in sequence on the oxidized layer.

5. The light emitting device according to claim 4, wherein the second mirror layer further comprises a lower spacing layer disposed under the oxidized layer.

6. The light emitting device according to claim 5, wherein the lower spacing layer comprises a plurality of lower spacing layers.

7. The light emitting device according to claim 4, wherein the oxidized layer comprises a first oxidized layer and a second oxidized layer disposed on the first oxidized layer.

8. The light emitting device according to claim 7, wherein lengths of the first oxidized layer are greater than lengths of the second oxidized layer.

9. The light emitting device according to claim 7, wherein a thickness of the first oxidized layer is different from a thickness of the second oxidized layer.

10. The light emitting device according to claim 7, wherein the second mirror layer further comprises an upper spacing layer between the first oxidized layer and the second oxidized layer.

11. The light emitting device according to claim 4, wherein the second mirror layer further comprises a plurality of sub-oxidized layers on an outer periphery of the second refractive index layer.

12. The light emitting device according to claim 11, wherein a length of each of the sub-oxidized layers from an edge of the sub-oxidized layer to a boundary of the sub-oxidized layer with the second refractive index layer is less than the lengths of the oxidized layer.

13. The light emitting device according to claim 11, wherein a boundary surface connecting boundaries between the plurality of sub-oxidized layers and the second refractive index layers forms a curved surface.

14. A light emitting device comprising:
a first mirror layer;
a second mirror layer disposed on the first mirror layer;
a cavity layer disposed between the first mirror layer and the second mirror layer and configured to generate light;
a mesa exposing side surfaces of the second mirror layer and the cavity layer,
a first pad region electrically connected to the first mirror layer; and
a second pad region at least partially disposed on the mesa and electrically connected to the second mirror layer,
wherein the second mirror layer comprises at least one oxidized layer forming an aperture through which light generated in the cavity layer is configured to pass,
wherein the second pad region comprises an open portion exposing an upper region of the mesa, and
wherein the open portion overlaps the aperture in plan view and has a diameter greater than a diameter of the aperture.

15. The light emitting device according to claim 14, wherein:
the second pad region comprises a contact region forming the open portion and a connecting region extending from the contact region; and
the contact region has a groove formed on an upper surface thereof.

16. The light emitting device according to claim 15, wherein the groove comprises a plurality of concave grooves arranged to be concentric with the open portion.

17. The light emitting device according to claim 14, further comprising:
a second electrode disposed on the mesa and electrically connected to the second mirror layer; and
an insulating layer disposed on the mesa and at least partially exposing the second electrode,
wherein the insulating layer comprises a plurality of sub-insulating layers.

18. A light emitting device comprising:
a first mirror layer;
a second mirror layer disposed on the first mirror layer;
a cavity layer disposed between the first mirror layer and the second mirror layer and configured to generate light; and
a mesa exposing side surfaces of the second mirror layer and the cavity layer,
wherein the second mirror layer comprises at least one oxidized layer forming an aperture through which light generated in the cavity layer is configured to pass, and a plurality of first and second refractive index layers repeatedly stacked in sequence on the oxidized layer, and
wherein a thickness of the oxidized layer is less than a thickness of the first or second refractive index layer.

19. The light emitting device according to claim 18, wherein a thickness of the uppermost first refractive index layer of the second mirror layer is greater than or equal to twice a thickness of the remaining first refractive index layers.

20. The light emitting device according to claim 18, wherein a thickness of the oxidized layer is in the range of 0.3 to 0.4 times a thickness of the first or second refractive index layer.
